(19) United States
(12) Patent Application Publication
(10) Pub. No.: US 2003/0007390 A1
(43) Pub. Date: Jan. 9, 2003

(54) Data output circuit of a memory device

(76) Inventors: Hyun-woo Lee, Icheon (KR); Seung-jong Yoo, Icheon (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/183,817

(22) Filed: Jun. 27, 2002

(30) Foreign Application Priority Data
Jun. 29, 2001 (KR) 2001-38507

(51) Int. Cl. G11C 5/00

(52) U.S. Cl. 365/189.05

(57) ABSTRACT

A data output circuit for a memory device is disclosed. By decoding plural data signals and by operating output transistors coupled to different driving voltages and having a single output terminal, the interface with an outside circuit is performed through the single output terminal. The output terminal outputs output signals having voltage levels different from each other. Thus, the number of interface terminals, the instant consumption of current, the area of a pad, and the area of a chip are reduced.

### BACKGROUND

1. Field of the Disclosure

The present disclosure relates to memory devices, and more particularly, to a data output circuit for a memory device.

2. Description of the Related Art

Memory is a general term for a storage device for storing data or commands used in a computer, communication system, or an image processing system, either temporarily or permanently. Memory is classified as a semiconductor type, a tape type, or an optical type. The semiconductor type is most widely used at present.

There are many kinds of semiconductor type memories; Dynamic Random Access Memory (DRAM), Static Random Access Memory (SRAM), Flash Memory, and Read Only Memory (ROM), which are classified on the basis of an electrical property of data storage type. Among those memories, DRAM is most widely used.

A memory device has interface terminals formed by a channel to transmit or receive data to/from an outside device. The number of interface terminals increases as the storage capacity of the memory device increases.

FIG. 1 is a circuit diagram showing a conventional data output circuit of a memory device.

As shown in FIG. 1, a pull-up output transistor 10 and a pull-down output transistor 20 are connected serially. A voltage source Vdd is connected to the drain of the pull-up output transistor 10, and a ground voltage Vss is connected to the source of the pull-down output transistor 20. A high level voltage or a low level voltage is output as a data signal from an output terminal OUT according to the on/off status of the pull-up output transistor 10 and the pull-down output transistor 20.

In other words, a high level data signal is output from the output terminal OUT when the pull-up output transistor 10 is turned on by a pull-up control signal PU, and a low level data signal is output from the output terminal OUT when the pull-down output transistor 20 is turned on by a pull-down control signal PD.

A large current must flow in order to drive many channels. For example, assuming that the current required to transmit a signal to an outside circuit is 40 mA, in a case of 32 DRAMs outputting data on 32 channels, a 1280 mA current will flow abruptly if all of the 32 interface terminals output high level voltages simultaneously.

Moreover, as the strength of the current is rapidly changed in a short time period by the continuous changing of the signals, the conductive lines are burdened with great voltages by the inductance of the conductive lines in an integrated circuit, and a drop in voltage applied from an outside may occur.

### SUMMARY OF THE INVENTION

In accordance with one aspect of the present invention, a data output circuit is provided for a memory device. The circuit includes an output portion having a plurality of output transistors that have a common output terminal. Each of the transistors are coupled to a different driving voltage. The circuit also includes a decoding portion to output control signals to turn on at least one of the plurality of output transistors, by combining a plurality of data signals.

### BRIEF DESCRIPTION OF THE DRAWINGS

FIG. 1 is a circuit diagram showing a conventional data output circuit of a memory device.

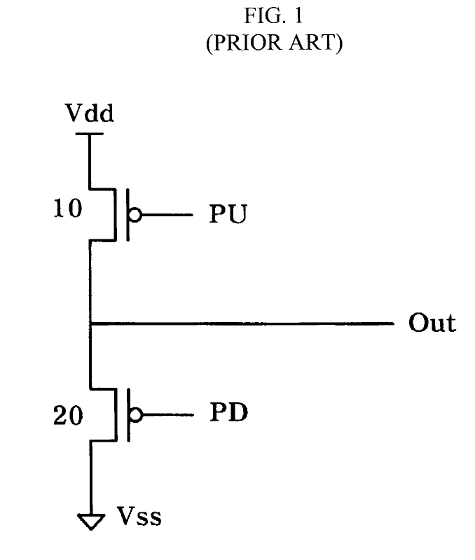

FIG. 2 is a circuit diagram showing an example data output circuit of a memory device constructed in accordance with the teachings of the present invention.

FIG. 3 is a graph showing an example output of the data output circuit of FIG. 2.

### DESCRIPTION OF THE PREFERRED EMBODIMENT

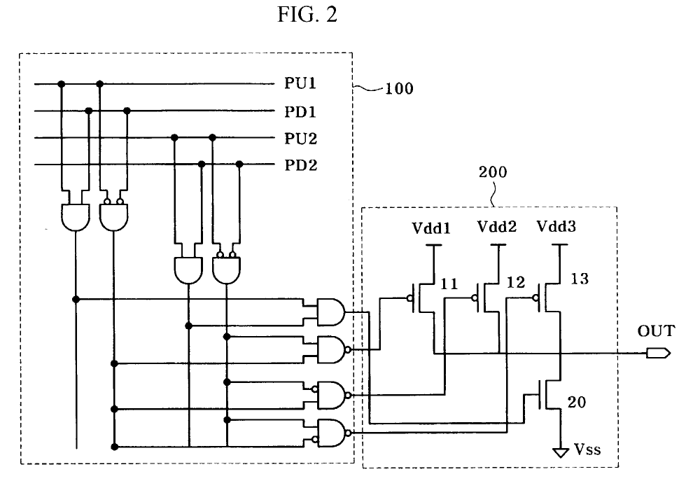

FIG. 2 is a circuit diagram showing an example data output circuit of a memory device. As shown in FIG. 2, the data output circuit has an output portion 200 and a decoding portion 100.

The output portion 200 is comprised of a first pull-up transistor 11 connected to a first voltage Vdd1, a second pull-up transistor 12 connected to a second voltage Vdd2, a third pull-up transistor 13 connected to a third voltage Vdd3, and a pull-down transistor 20 for pulling-down to a ground voltage Vss. The output transistors 11, 12, 13 and 20 have a common output terminal OUT.

The decoding portion 100 outputs four output signals by combining a first pull-up control signal PU1 and a first pull-down control signal PD1 for outputting a first data signal, and a second pull-up control signal PU2 and a second pull-down control signal PD2 for outputting a second data signal. The decoding portion 100 selectively turns on the first, second and third pull-up output transistors 11, 12 and 13 and the pull-down transistor 20 of the output portion 200 in response to the four output signals.

In this situation, the number of the output signals output by the decoding portion 100 is (the number of the data signals)2. In the illustrated example, the number of output signals output from the decoding portion 100 is four since the number of the data signals is two. The output portion 200 outputs the output signals having different voltages from each other through the single output terminal OUT.

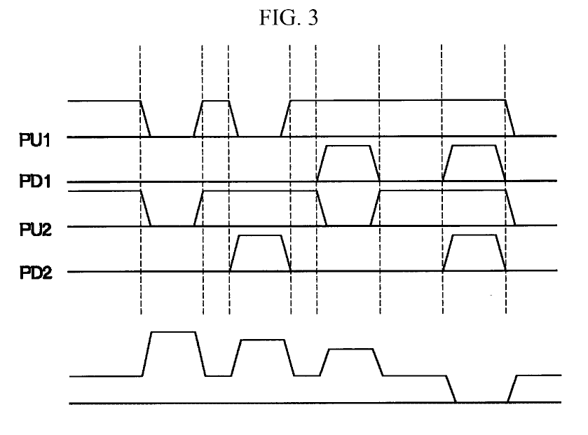

FIG. 3 is a graph showing an example output of the data output circuit of FIG. 3. As shown in FIG. 3, four voltages, Vdd1, Vdd2, Vdd3 and Vss, are output as the output signals. The voltage Vdd1 indicates that all of the first data signal and the second data signal are high. The voltage Vdd2 indicates that the first data signal is high and the second data signal is low. The voltage Vdd3 indicates that the first data signal is low and the second data signal is high. The voltage Vdd4 indicates that all of the first data signal and the second data signal are low. Accordingly, since two data signals can be output through the single output terminal OUT, the number of output terminals OUT can be reduced to half.

In other words, if the first data signal and the second data signal are high, all of the first and the second pull-up control signals PU1 and PU2, and the first and the second pull-down control signal PD1 and PD2 are low. Therefore, by the first and the second pull-up control signals PU1 and PU2 and the first and the second pull-down control signal PD1 and PD2, the output signals decoded and output by the decoding portion 100 turn on the first pull-up output transistor 11 and turn off the pull-down output transistor 20 and the first and the second pull-up output transistors 11 and 12, whereby the output terminal OUT outputs the voltage Vdd1.

Furthermore, if the first data signal and the second data signal are low, all of the first and the second pull-up control signals PU1 and PU2, and the first and the second pull-down control signal PD1 and PD2 are high. Therefore, by the first and the second pull-up control signals PU1 and PU2 and the first and the second pull-down control signals PD1 and PD2, the output signals decoded and output by the decoding portion 100 turn on the pull-down output transistor 20, and turn off the first, the second, and the third pull-up output transistors 11, 12 and 13, whereby the output terminal OUT outputs the voltage Vss.

According to a similar method, the voltage Vdd2 is output from the output terminal OUT if the first data signal is high and the second data signal is low, and the voltage Vdd3 is output from the output terminal OUT if the first data signal is low and the second data signal is high.

As described above, the output transistors coupled to different driving voltages and having a single output terminal are driven by decoding a plurality of data signals, to interface with an outside through the single output terminal using a plurality of output signals having voltage levels different from each other, and whereby the number of interface terminals, the instant consumption of current, the area of a pad, and the area of a chip are reduced.

Although certain apparatus and methods have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. A data output circuit for a memory device, comprising:
an output portion having a plurality of output transistors that have a common output terminal, each of the output transistors being coupled to a different driving voltages; and
a decoding portion to output control signals to turn on at least one of the plurality of output transistors, by combining a plurality of data signals.

2. A data output circuit as defined in claim 1, wherein the output portion comprises:
a pull-down transistor to output a pull-down voltage in response to a first output value of the decoding portion;
a first pull-up transistor to output a first voltage in response to a second output value of the decoding portion;
a second pull-up transistor to output a second voltage in response to a third output value of the decoding portion; and
a third pull-up transistor to output a third voltage in response to a fourth output value of the decoding portion.

3. A data output circuit as defined in claim 1, wherein a number of output signals output by the decoding portion equals a square of a number of the data signals, and the data signals are pull-up control signals and pull-down control signals.

4. A data output circuit as defined in claim 1, wherein the output portion selectively outputs a number of different voltage levels, and wherein the number of levels equals a square of a number of data signals.
